(19) United States
(12) Patent Application Publication
(10) Pub. No.: US 2026/0026128 A1
(43) Pub. Date: Jan. 22, 2026

(54) IMAGE SENSOR PACKAGE AND METHOD OF MANUFACTURING THE SAME

(71) Applicant: Samsung Electronics Co., Ltd., Suwon-si (KR)

(72) Inventor: Kyongsoon CHO, Suwon-si (KR)

(73) Assignee: Samsung Electronics Co., Ltd., Suwon-si (KR)

(21) Appl. No.: 19/096,796

(22) Filed: Apr. 1, 2025

(30) Foreign Application Priority Data
Jul. 18, 2024 (KR) 10-2024-0094784

(51) Int. Cl. H10F 39/00

(52) U.S. Cl. CPC H10F 39/811; H10F 39/011; H10F 39/804

(57) ABSTRACT

An image sensor package including a package substrate defining an opening region, the package substrate including a plurality of bonding pads; a logic chip on the package substrate, the logic chip including a substrate and an interconnection structure; an image sensor chip on the logic chip, the image sensor chip including an active pixel sensor region and a non-sensing region having a plurality of chip pads; an interface chip in the opening region of the package substrate, the interface chip including an active surface including a plurality of active pads, and opposing a lower surface of the logic chip; and an inactive surface opposite the active surface, and the logic chip including first through-electrode structures penetrating the substrate of the logic chip and electrically connecting the interconnection structure of the logic chip and the plurality of active pads of the interface chip.

### CROSS-REFERENCE TO RELATED APPLICATION(S)

This application claims benefit of priority to Korean Patent Application No. 10-2024-0094784 filed on Jul. 18, 2024 in the Korean Intellectual Property Office, the disclosure of which is incorporated herein by reference in its entirety.

### BACKGROUND

Example embodiments of the present disclosure relate to image sensor packages and methods of manufacturing the same.

As electronic devices have been designed to have a reduced weight and high performance, development of semiconductor packages having a reduced size and high performance has also been desirable in the image sensor package field. Research and development have been continuously conducted to implement miniaturization, high performance, and high reliability of an image sensor package.

### SUMMARY

Some example embodiments of the present disclosure are to improve image sensor packages including a package substrate in which an opening is formed and a chip structure disposed in the opening, and methods of manufacturing the same.

According to some example embodiments of the present disclosure, an image sensor package includes a package substrate defining an opening region, the package substrate including a plurality of bonding pads; a logic chip on the package substrate, the logic chip including a substrate and an interconnection structure; an image sensor chip on the logic chip, the image sensor chip including an active pixel sensor region and a non-sensing region having a plurality of chip pads; an interface chip in the opening region of the package substrate, the interface chip including an active surface including a plurality of active pads, the active surface opposing a lower surface of the logic chip; and an inactive surface opposite the active surface, and the logic chip including first through-electrode structures penetrating the substrate of the logic chip and electrically connecting the interconnection structure of the logic chip and the plurality of active pads of the interface chip.

According to some example embodiments of the present disclosure, an image sensor package includes a package substrate defining an opening region; and a first logic chip on the package substrate, the first chip covering the opening region, the first logic chip including a substrate; an insulating structure on the substrate, the insulating structure including conductive patterns; a passivation layer on a lower portion of the substrate; and through-electrode structures penetrating the substrate and the passivation layer and electrically connected to the conductive patterns, and an image sensor chip on an upper portion of the first logic chip; and a second logic chip on a lower portion of the first logic chip in the opening region of the package substrate and electrically connected to the through-electrode structures of the first logic chip.

According to some example embodiments of the present disclosure, an image sensor package includes a package substrate defining an opening region, the package substrate including a plurality of bonding pads; and a logic chip on the package substrate, the logic chip covering the opening region, the logic chip including a substrate; a lower insulating structure on the substrate; an upper insulating structure on the lower insulating structure, the upper insulating structure including a plurality of circuit interconnection patterns; a passivation layer on a lower portion of the substrate; and through-electrode structures penetrating the passivation layer, the substrate, and the lower insulating structure and in contact with a lowermost circuit interconnection pattern among the plurality of circuit interconnection patterns, and an image sensor chip on the logic chip, the image sensor chip including an active pixel sensor region and non-sensing region having and a plurality of chip pads; a conductive wire electrically connecting the plurality of bonding pads of the package substrate and the plurality of chip pads of the image sensor chip; and an interface chip on a lower portion of the logic chip in the opening region of the package substrate and electrically connected to the through-electrode structures of the logic chip.

### BRIEF DESCRIPTION OF DRAWINGS

The above and other aspects, features, and advantages of the present disclosure will be more clearly understood from the following detailed description, taken in combination with the accompanying drawings, in which:

FIG. 1 is a cross-sectional diagram illustrating an image sensor package according to some example embodiments of the present disclosure;

FIG. 2 is an enlarged diagram illustrating an image sensor package according to some example embodiments of the present disclosure;

FIG. 3 is an enlarged diagram illustrating an image sensor package according to some example embodiments of the present disclosure;

FIG. 4 is an enlarged diagram illustrating an image sensor package according to some example embodiments of the present disclosure;

FIG. 5 is an enlarged diagram illustrating an image sensor package according to some example embodiments of the present disclosure;

FIG. 6 is a cross-sectional diagram illustrating an image sensor package according to some example embodiments of the present disclosure;

FIG. 7 is a cross-sectional diagram illustrating an image sensor package according to some example embodiments of the present disclosure;

FIG. 8 is an enlarged diagram illustrating a portion of an image sensor package according to some example embodiments of the present disclosure;

FIG. 9 is a cross-sectional diagram illustrating an image sensor package according to some example embodiments of the present disclosure;

FIGS. 10 to 15 are cross-sectional diagrams illustrating processes of a method of manufacturing an image sensor package in order according to some example embodiments of the present disclosure; and

FIGS. 16 and 17 are cross-sectional diagrams illustrating processes of a method of manufacturing an image sensor package in order according to some example embodiments of the present disclosure.

### DETAILED DESCRIPTION

Hereinafter, example embodiments of the present disclosure will be described as follows with reference to the accompanying drawings.

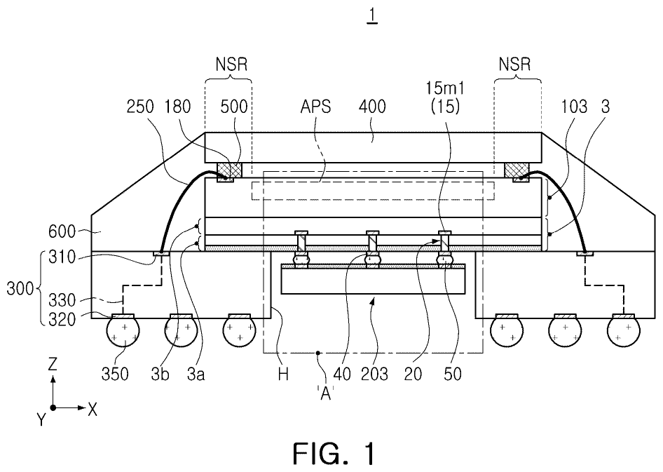

FIG. 1 is a cross-sectional diagram illustrating an image sensor package according to some example embodiments.

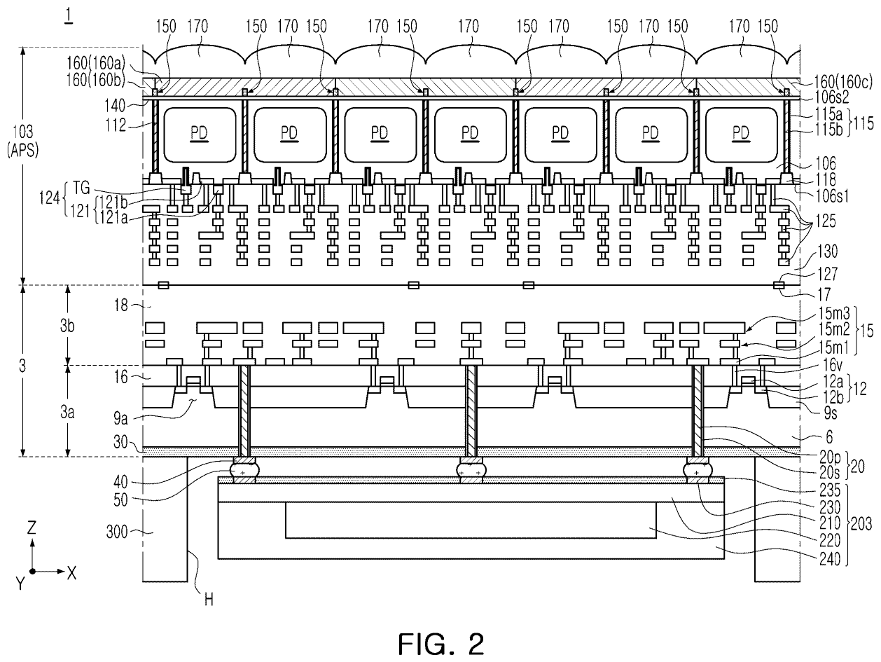

FIG. 2 is an enlarged diagram illustrating an image sensor package according to some example embodiments.

Referring to FIGS. 1 and 2, an image sensor package 1 may include a first chip structure 3, a second chip structure 103, a third chip structure 203, a package substrate 300, a cover glass 400, a bonding dam 500, and an encapsulation layer 600.

The second chip structure 103 may be disposed on the first chip structure 3. In some example embodiments, the first chip structure 3 may be configured as a logic chip, and the second chip structure 103 may be configured as an image sensor chip. In some example embodiments, the first chip structure 3 may be configured as a chip stack structure including a logic chip and a memory chip. The third chip structure 203 may be disposed on a lower portion of the second chip structure 103. In some example embodiments, the third chip structure 203 may be configured as a logic chip. The third chip structure 203 may be configured as an interface chip enabling smooth data transmission between the first and second chip structures 3 and 103, for example. In some example embodiments, the third chip structure 203 may be provided in the form of a package including an interface chip. The first to third chip structures 3, 103, and 203 may be organically connected to each other and operated.

The package substrate 300 may be configured as a support substrate on which the first and second chip structures 3 and 103 are mounted, and may be configured as a semiconductor package substrate including a printed circuit board (PCB), a ceramic substrate, a glass substrate, a tape interconnection substrate, or the like. A body of the package substrate 300 may include different materials depending on the type of the substrate. For example, when the package substrate 300 is implemented as a printed circuit board, an interconnection layer may be further stacked on a cross-sectional surface or both surfaces of a body copper-clad laminate or a copper-clad laminate.

The package substrate 300 may include a region having an opening. The opening may include a through-hole H penetrating a front surface and a rear surface of the package substrate 300. The third chip structure 203 may be disposed in the through-hole H.

The package substrate 300 may include a front pad 310, a back pad 320, and an interconnection 330.

The front pad 310 may be disposed such that an upper surface thereof may be exposed to an upper portion of the package substrate 300. The front pad 310 may include, for example, at least one of aluminum (Al), copper (Cu), nickel (Ni), tungsten (W), platinum (Pt), or gold (Au). The back pad 320 may be disposed on a lower portion of the package substrate 300. The back pad 320 may include the same or substantially the same material as a material of the front pad 310. The interconnection 330 may form an electrical path connecting the front pad 310 to the back pad 320. The interconnection 330 may include a plurality of interconnection layers. Each of the plurality of interconnection layers may include a metal material, for example, at least one metal among copper (Cu), aluminum (Al), nickel (Ni), silver (Ag), gold (Au), platinum (Pt), tin (Sn), lead (Pb), titanium (Ti), chromium (Cr), palladium PD, indium (In), zinc (Zn) and carbon (C), and/or an alloy including two or more metals.

A plurality of external connection terminals 350 electrically connected to the back pad 320 and the interconnection layer 330 may be disposed on a lower surface of the package substrate 300. The external connection terminals 350 may include tin (Sn), indium (In), bismuth (Bi), antimony (Sb), copper (Cu), silver (Ag), zinc (Zn), lead (Pb) and/or alloys thereof.

The first chip structure 3 may include a first region 3a and a second region 3b. The first region 3a may include a first substrate 6, a device isolation film 9s defining an active region 9a on the first substrate 6, a circuit device 12 on the first substrate 6, and a lower insulating layer 16 covering the lower contact plug 16v. The second region 3b may include a first interconnection structure 15 and an upper insulating layer 18 covering the first interconnection structure 15. In some example embodiments, the lower insulating layer may be referred to as a lower insulating structure, and the upper insulating layer may be referred to as an upper insulating structure. In some example embodiments, the lower and upper insulating layers may be collectively referred to as the first insulating layer.

The first substrate 6 may be configured as a semiconductor substrate. For example, the first substrate 6 may be configured as a substrate formed of a semiconductor material, for example, a single crystal silicon substrate. The device isolation film 9s may define the active region 9a on the first substrate 6. The device isolation film 9s may be formed of an insulating material, such as silicon oxide. The circuit device 12 may include a device, such as a transistor, including a gate 12a and a source/drain 12b. The lower contact plug 16v may be configured as a conductive pattern in contact with the source/drain 12b and electrically connected to the source/drain 12b. The first interconnection structure 15 may be configured as a conductive pattern electrically connected to the lower contact plug 16v. The first interconnection structure 15 may include a plurality of interconnection portions and a plurality of via portions. The first interconnection structure 15 may include, for example, a first circuit interconnection pattern 15m1 in contact with the lower contact plug 16v, a second circuit interconnection pattern 15m2 including a via portion in contact with the first circuit interconnection pattern 15m1 and an interconnection portion in contact with the via portion, and a third circuit interconnection pattern 15m3 on the second circuit interconnection pattern 15m2.

The second region 3b may further include a first chip pad 17. The first chip pad 17 may be disposed on an upper portion of the backside structure BS and may be in contact with a second chip pad 127 of the second chip structure 103. In some example embodiments, the first chip pad 17 and the second chip pad 127 may be configured to be in contact with each other and bonding the first chip structure 3 to the second chip structure 103.

In some example embodiments, the first chip structure 3 may further include through-electrode structures 20.

The through-electrode structures 20 may penetrate the first substrate 6, the device isolation film 9s, and the lower insulating layer 16. An upper surface of the through-electrode structures 20 may be present on the same or substantially the same plane as an upper surface of the lower insulating layer 16. The upper surface of the through-electrode structures 20 may be in contact with the first circuit interconnection pattern 15m1 on a lower surface of the upper insulating layer 18. Accordingly, the through-electrode structures 20 may be electrically connected to the first interconnection structure 15. At least a portion of the through-electrode structures 20 may vertically overlap a region in which a through-hole H of the package substrate 300 is formed.

The through-electrode structures 20 may include a pillar pattern 20p and an insulating spacer 20s surrounding a side surface of the pillar pattern 20p. The pillar pattern 20p may include copper (Cu), but some example embodiments thereof are not limited thereto, and may include a different conductive material. The insulating spacer 20s may include silicon oxide. Accordingly, the insulating spacer 20s may isolate the pillar pattern 20p and the first substrate 6 from each other.

In some example embodiments, the first chip structure 3 may further include a backside insulating layer 30. According to some example embodiments, the backside insulating layer 30 may be referred to as a passivation layer.

The backside insulating layer 30 may be disposed on a lower surface of the first substrate 6 and may surround a side surface of a lower region of the through-electrode structure 20. The backside insulating layer 30 may be attached to an upper surface of the package substrate 300 and may cover a region in which the through-hole H is formed.

In some example embodiments, the first chip structure 3 may further include lower pads 40.

The lower pads 40 may be formed on a lower portion of the through-electrode structure 20. In other words, the backside insulating layer 30 may cover a lower surface of the through-electrode structure 20 in a region in which the through-hole H is formed. The lower pads 40 may include a conductive metal. The plurality of upper pads 180 may include at least one of, for example, aluminum (Al), copper (Cu), nickel (Ni), tungsten (W), platinum (Pt), or gold (Au).

The second chip structure 103 may include a second substrate 106 including a first surface 106s1 and a second surface 106s2, an active pixel sensor region APS having a plurality of unit pixels disposed in an array form, and a non-sensing region NSR.

The active pixel sensor region APS may be a region to which light is incident. The non-sensing region NSR may be disposed on an edge of the second chip structure 103 to surround the active pixel sensor region APS. A plurality of upper pads 180 may be formed in the non-sensing region NSR. The plurality of upper pads 180 may include a conductive metal. The plurality of upper pads 180 may include, for example, at least one of aluminum (Al), copper (Cu), nickel (Ni), tungsten (W), platinum (Pt), or gold (Au).

When the second chip structure 103 is formed with backside illumination (BSI), the active pixel sensor region APS and the plurality of upper pads 180 may be formed on a back surface of the second substrate 106, but some example embodiments thereof are not limited thereto. For example, when the second chip structure 103 is formed with frontside illumination (FSI), the active pixel sensor region APS and the plurality of upper pads 180 may be formed on a front surface of the second substrate 106 (not illustrated).

The second substrate 106 may be configured as a semiconductor substrate. For example, the second substrate 106 may be formed of a semiconductor material, for example, a single crystal silicon substrate. The first surface 106s1 of the second substrate 106 may be in contact with the second insulating layer 130.

Photoelectric conversion devices PD may be disposed in the second substrate 106. The photoelectric conversion devices PD may generate and accumulate electric charges corresponding to incident light. For example, the photoelectric conversion devices PD may include photodiodes, phototransistors, photogates, pinned photo diodes (PPD), and combinations thereof. In some example embodiments, the photoelectric conversion devices PD may be disposed in the active pixel sensor region APS.

In some example embodiments, the second chip structure 103 may further include an isolation structure 115. The isolation structure 115 may be disposed to surround each of the photoelectric conversion devices PD. The isolation structure 115 may be disposed in a through-opening 112 penetrating the second substrate 106. The isolation structure 115 may penetrate the second substrate 106. The through-opening 112 may be connected to a device isolation film 118. Accordingly, the isolation structure 115 may be connected to a device isolation film 118. The device isolation film 118 may be disposed on the first surface 106s1 of the second substrate 106 and may define an active region. The device isolation film 118 may be formed of an insulating material, such as silicon oxide.

In some example embodiments, the isolation structure 115 may include an isolation insulating layer 115a covering side surfaces of the isolation pattern 115b and the isolation pattern 115b. For example, the isolation insulating layer 115a may include silicon oxide, and the isolation pattern 115b may include polysilicon.

In some example embodiments, the second chip structure 103 may further include a second circuit device 124 disposed between the first surface 106s1 of the second substrate 106 and the first chip structure 3. The second circuit device 124 may include a transfer gate TG and active devices 121. The active devices 121 may be configured as a transistor including a gate 121a and a source/drain 121b. The transfer gate TG may transfer electric charges from an adjacent photoelectric conversion device PD to an adjacent floating diffusion region, and the active devices 121 may be configured as at least one of a source follower transistor, a reset transistor, or a select transistor. The transfer gate TG may be configured as a vertical transistor gate including a portion extending from a first surface 106s1 of the second substrate 106 into the second substrate 106.

In some example embodiments, the second chip structure 103 may further include a second interconnection structure 125.

The second interconnection structure 125 may include interconnections of multiple layers disposed at different height levels and vias electrically connecting the interconnections of the multiple layers and electrically connecting the interconnections of the multiple layers to the second circuit device 124.

In some example embodiments, the second chip structure 103 may further include a second chip pad 127. The second chip pad 127 may be disposed on a lower portion of the second chip structure 103 and in contact with the first chip pad 17 of the first chip structure 3. In some example embodiments, the first chip pad 17 and the second chip pad 127 may be components configured to be in contact with each other and to bond the first chip structure 3 to the second chip structure 103. At least a portion of the second chip pads 127 may be electrically connected to the second interconnection structure 125.

In some example embodiments, the second chip structure 103 may further include a second insulating layer 130 covering the second circuit device 124 and the second interconnection structure 125 between the first surface 106s1 of the second substrate 106 and the first chip structure 3.

The second insulating layer 130 may be in contact with and bonded to the first insulating layer (or “upper insulating layer”) 18. Each of the first and second insulating layers 18 and 130 may be formed as multiple layers including different types of insulating layers. For example, the second insulating layer 130 may be formed as multiple layers including at least two types of a silicon oxide layer, a low-K dielectric layer, and a silicon nitride layer.

In some example embodiments, the second chip structure 103 may further include a horizontal insulating layer 140 disposed on the second surface 106s2. The horizontal insulating layer 140 may cover the isolation structure 115.

In some example embodiments, the horizontal insulating layer 140 may include a plurality of layers stacked in sequence. The horizontal insulating layer 140 may include an anti-reflective layer which may reduce or prevent reflection of light occurring due to a sharp change in refractive index on the second surface 106s2 of the second substrate 106 formed of silicon. For example, the horizontal insulating layer 140 may include at least two or more layers of an aluminum oxide layer, a hafnium oxide layer, a silicon oxynitride layer, a silicon oxide layer, and/or a silicon nitride layer. For example, the horizontal insulating layer 140 may include first to fourth layers stacked in sequence. The first layer may be an aluminum oxide layer, each of the second and fourth layers may be a hafnium oxide layer, and the third layer may be a silicon oxide layer.

The horizontal insulating layer 140 may be disposed to extend from the active pixel sensor region APS to the non-sensing region NSR. The horizontal insulating layer 140 may be formed to have the same or substantially the same thickness and an upper surface of the same level in the active pixel sensor region APS and the non-sensing region NSR.

In some example embodiments, the second chip structure 103 may further include a grid pattern 150 on the horizontal insulating layer 140.

The grid pattern 150 may be disposed on the horizontal insulating layer 140 in the active pixel sensor region APS. The grid pattern 150 may be disposed between a plurality of pixel regions. The grid pattern 150 may be an insulating material, for example, a low refractive index (LRI) material, such as an oxide or nitride including Si, Al, or a combination thereof. Also, the grid pattern 150 may include porous silicon oxide or network-structured silica nanoparticles.

In some example embodiments, the grid pattern 150 may be configured as a double-layer structure including a first layer formed of a conductive material and a second layer formed of an insulating material disposed on the first layer, and may be configured as a combination of a double-layer structure and a single-layer structure. However, the number of layers and materials of the grid pattern 150 are not limited thereto and may be varied.

In some example embodiments, the second chip structure 103 may further include color filters 160 covering the horizontal insulating layer 140 and the grid pattern 150 and microlenses 170.

The color filters 160 may be disposed on the horizontal insulating layer 140 and may cover the horizontal insulating layer 140 and the grid pattern 150. The color filters 160 may allow light of a specific wavelength to pass therethrough and to reach the photoelectric conversion devices PD. The color filters 160 may include first to third color filters 160a, 160b, and 160c of different first to third colors. For example, the first color may be a green color, the second color may be a red color, and the third color may be a blue color. The color filters 160 may be formed of a material including, for example, a pigment including a metal or a metal oxide mixed with resin. A thickness of each of the color filters 160 may be greater than ae thickness of the grid pattern 150. Accordingly, the color filters 160 may cover an upper surface and side surfaces of the grid pattern 150 on the horizontal insulating layer 140.

Microlenses 170 may be disposed on the color filters 160. Each of the microlenses 170 may have a convex shape in a direction away from the first chip structure 3, for example in a direction away from the second substrate 106. The microlenses 170 may focus incident light into the photoelectric conversion devices PD. The microlenses 170 may be formed of a transparent photoresist material and/or a transparent thermosetting resin material. For example, the microlenses 170 may be formed of a TMR™ series vertical (a product of Tokyo Ohka Kogo, Co.) or an MFR™ series resin (a product of Japan Synthetic Rubber Corporation), but some example embodiments thereof are not limited to these materials.

The third chip structure 203 may include a base substrate 210, a semiconductor chip 220 on the base substrate 210, and an encapsulant 240 covering the semiconductor chip 220 on the base substrate 210.

The base substrate 210 may be configured as a support substrate on which the semiconductor chip 220 is mounted, and may be configured as a substrate for a semiconductor package including a printed circuit board (PCB), a ceramic substrate, a glass substrate, a tape interconnection substrate, or the like. A body of the base substrate 210 may include different materials depending on the type of the substrate. For example, when the base substrate 210 is implemented as a printed circuit board, an interconnection layer may be further stacked on a cross-sectional surface or both surfaces of a body copper-clad laminate or a copper-clad laminate.

The semiconductor chip 220 may include a logic chip. The semiconductor chip 220 may be configured as an interface chip enabling smooth data transmission between the first and second chip structures 3 and 103. The semiconductor chip 220 may include an active surface on which a plurality of active pads are formed and an inactive surface on an opposite side of the active surface. The semiconductor chip 220 may be mounted on the base substrate 210 such that the active surface may oppose the base substrate 210.

The encapsulant 240 may be formed by applying an adhesive such as an epoxy molding compound (EMC).

The third chip structure 203 may further include active pads 230 and an insulating layer 235 formed on the base substrate 210. The insulating layer 235 may surround a side surface of the active pads 230 on the base substrate 210.

The third chip structure 203 may be disposed in the through-hole H of the package substrate 300. In the through-hole H, the first and third chip structures 3 and 203 may be disposed such that the insulating layers 30 and 235 may be disposed to oppose each other. In other words, the third chip structure 203 may be disposed such that active pads 230 thereof may be disposed to oppose the lower pads 40 of the first chip structure 3. Connection bumps 50 may be disposed between the active pads 230 and the lower pads 40. Accordingly, the first and third chip structures 103 and 203 may be electrically connected to each other by the through-electrode structure 20.

The third chip structure 203 may be disposed between levels of an upper surface and a lower surface of the package substrate 300. For example, a level of an upper surface of the third chip structure 203 may be lower than a level of an upper surface of the package substrate 300, and a level of a lower surface of the third chip structure 203 may be higher than a level of a lower surface of the package substrate 300.

According to some example embodiments, as the third chip structure 203 is disposed in the through-hole H region, a more compact image sensor package may be provided. Also, as the third chip structure 203 is physically spaced apart from the external connection terminals 350, physical damage received from the external connection terminals 350 when the third chip structure 203 is mounted may be reduced or prevented. Also, by the through-electrode structure 20, a signal delay between the first to third chip structures 3, 103, and 203 may be improved.

The image sensor package 1 may further include a conductive wire 250 connecting a front pad 310 of the package substrate 300 to an upper pad 180 of the second chip structure 103. The second chip structure 103 may be electrically connected to an interconnection 330 disposed on the package substrate 300 through the conductive wire 250.

The bonding dam 500 may be disposed to surround the active pixel sensor region APS in an edge region of an upper portion of the second chip structure 103. In a different view, the bonding dam 500 may be formed in a non-sensing region NSR. The bonding dam 500 may be formed to cover a plurality of upper pads 180 in the non-sensing region NSR, but some example embodiments thereof are not limited thereto. The bonding dam 500 may be disposed, for example, between the plurality of upper pads 180 and the active pixel sensor region APS, to not vertically overlap the plurality of upper pads 180 and the active pixel sensor region APS. The bonding dam 500 may include an engineering plastic, for example, polyamide (PA), polycarbonate (PC), liquid crystal polymer (LCP), and combinations thereof.

The cover glass 400 may be provided on the bonding dam 500 and may be spaced apart from and may oppose the second chip structure 103. Accordingly, a gap may be formed between the second chip structure 103 and the cover glass 400. The cover glass 400 may include a transparent material, such as glass, to allow light to pass therethrough.

The encapsulation layer 600 may cover a side surface of the cover glass 400 on the package substrate 300, an edge of the lower surface of the cover glass 400, a side surface of the bonding dam 500, an edge of the upper surface of the first and second chip structures 3 and 103, a side surface of the first and second chip structures 3 and 103, and the conductive wire 250. The encapsulation layer 600 may be formed by applying an adhesive, for example, an epoxy molding compound (EMC).

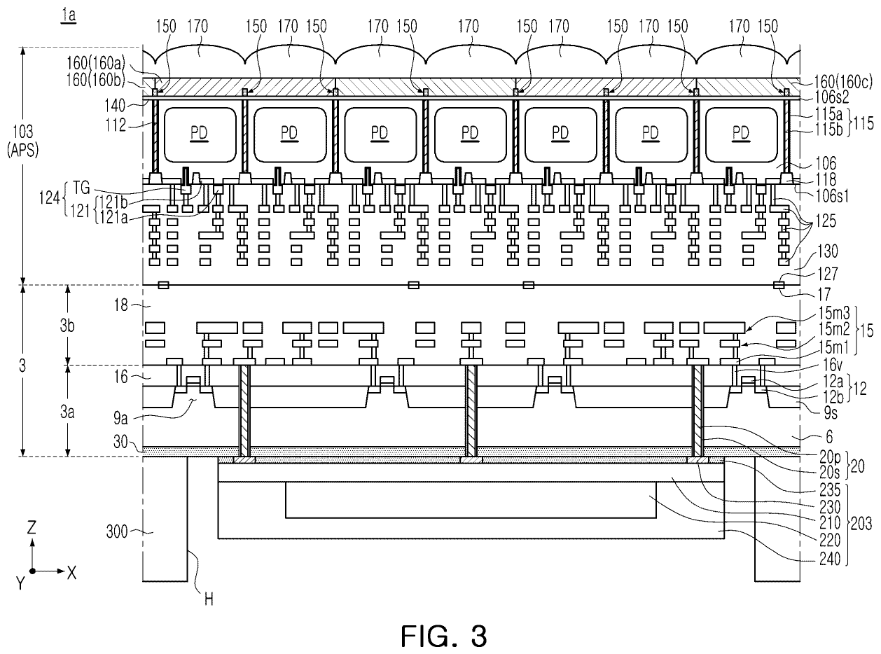

FIG. 3 is an enlarged diagram illustrating an image sensor package according to some example embodiments.

Referring to FIG. 3, the image sensor package 1a may be the same as or similar to the configuration described with reference to FIG. 1 and FIG. 2, other than the configuration in which the first and third chip structures 3 and 203 are physically in contact with and connected.

The third chip structure 203 may be physically in contact with and connected to the first chip structure 3 in the region in which the through-hole H is formed. The backside insulating layer 30 of the first chip structure 3 and the insulating layer 235 of the third chip structure 203 may be in contact with and bonded to each other. In a different view, the through-electrode structures 20 of the first chip structure 3 and the active pads 230 of the third chip structure 203 may be in contact with and bonded to each other. A horizontal width of the active pads 230 may be greater than a horizontal width of the through-electrode structures 20.

In the through-hole H region, a level of an upper surface of the third chip structure 203 may be on the same or substantially the same plane as a level of an upper surface of the package substrate 300.

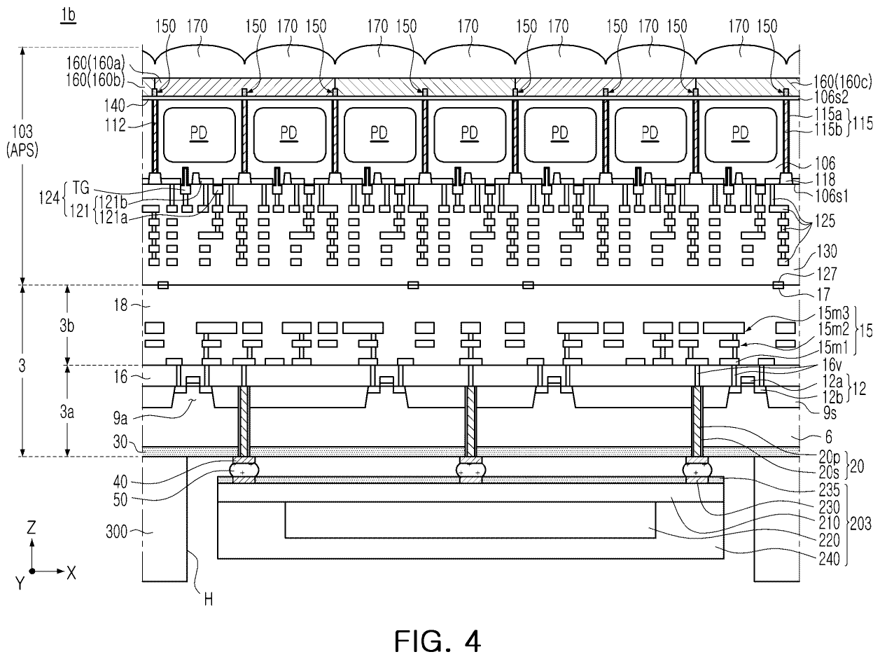

FIG. 4 is an enlarged diagram illustrating an image sensor package according to some example embodiments.

Referring to FIG. 4, the image sensor package 1b may be the same as or similar to the configuration described with reference to FIGS. 1 to 3, other than the configuration in which at least a portion of the through-electrode structures 20 is connected to the lower contact plug 16v.

At least a portion of the through-electrode structures 20 may penetrate the first substrate 6 and the device isolation film 9s and may be in contact with a lower surface of the lower contact plug 16v. An upper surface of the through-electrode structures 20 may be on the same or substantially the same plane as an upper surface of the device isolation film 9s. At least a portion of an upper surface of the through-electrode structures 20 may be covered by a lower insulating layer 16.

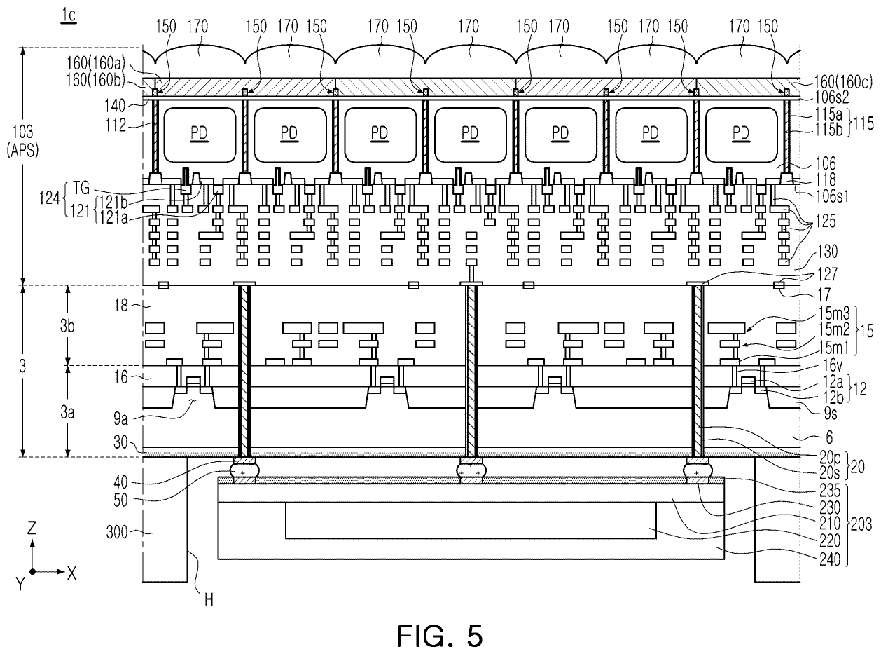

FIG. 5 is an enlarged diagram illustrating an image sensor package according to some example embodiments.

Referring to FIG. 5, an image sensor package 1c may be the same as or similar to the configuration described with reference to FIGS. 1 to 4, other than the configuration in which at least a portion of the through-electrode structures 20 is connected to the second chip pad 127.

At least a portion of the through-electrode structures 20 may penetrate the first substrate 6, the device isolation film 9s, and the lower and upper insulating layers 16 and 18 and may be in contact with a lower surface of the second chip pad 127 of the second chip structure 103. At least a portion of the second chip pads 127 may be electrically connected to the second interconnection structure 125. Accordingly, in some example embodiments, the third chip structure 203 may be electrically connected to the second chip structure 103 through the through-electrode structures 20. An upper surface of the through-electrode structures 20 may be on the same or substantially the same plane as an upper surface of the upper insulating layer 18.

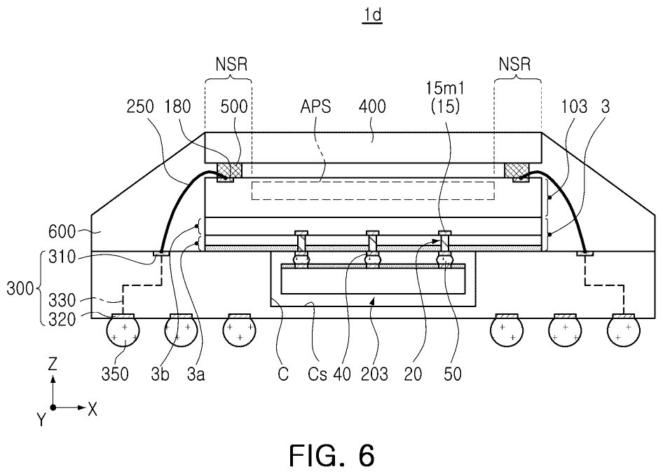

FIG. 6 is a cross-sectional diagram illustrating an image sensor package according to some example embodiments.

Referring to FIG. 6, an image sensor package 1d may be the same as or similar to the configuration described with reference to FIGS. 1 to 5, other than the configuration in which an opening of the package substrate 300 may include a cavity C recessed into an upper portion of the package substrate 300.

The cavity C of the package substrate 300 may be defined as a region formed by at least a portion of the package substrate 300 being recessed. Accordingly, the package substrate 300 may be defined to have a bottom surface Cs in the cavity C region. In a different view, the cavity C may be recessed into at least a portion of the package substrate 300 and may be defined by a bottom surface Cs of the package substrate 300. Accordingly, a lower surface of a third chip structure 203 disposed in the cavity C may oppose a bottom surface Cs of the package substrate 300. In a different view, side surfaces and lower surface of the third chip structure 203 may be surrounded by the package substrate 300.

In some example embodiments, at least portions of the third chip structure 203 and the external connection terminals 350 may vertically overlap each other.

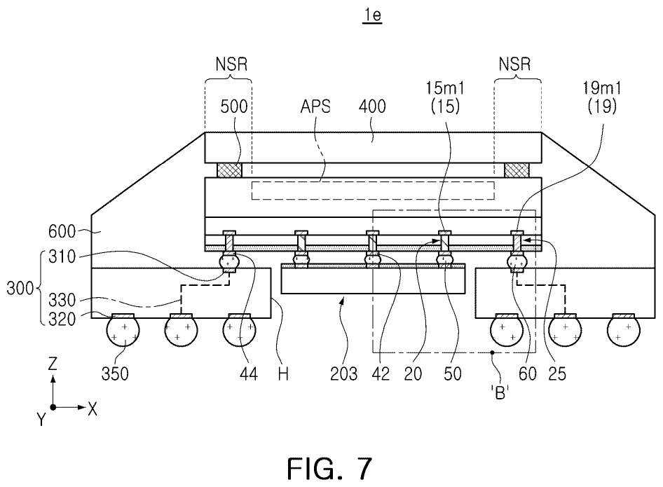

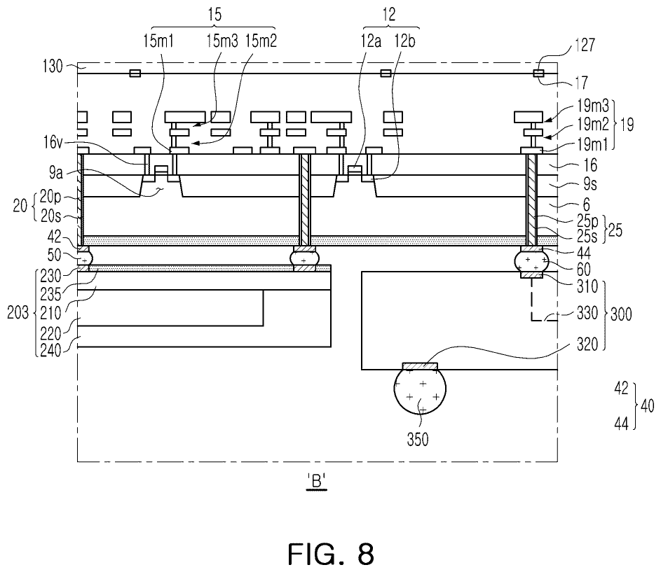

FIG. 7 is a cross-sectional diagram illustrating an image sensor package according to some example embodiments. FIG. 8 is an enlarged diagram illustrating region “B” in FIG. 7 according to some example embodiments.

Referring to FIGS. 7 and 8, an image sensor package 1e may be the same as or similar to the configuration described with reference to FIGS. 1 to 6 other than the configuration in which the first chip structure 3 further includes through-electrode structures 25 formed in the non-sensing region NSR. In some example embodiments, the through-electrode structures 20 formed in the active pixel sensor region APS may be referred to as first through-electrode structures 20, and the through-electrode structures 25 formed in the non-sensing region NSR may be referred to as second through-electrode structures 25.

In some example embodiments, the first chip structure 3 may further include peripheral interconnection structures 19 formed in the non-sensing region NSR. The peripheral interconnection structure 19 may include a first peripheral circuit interconnection pattern 19m1, a second peripheral circuit interconnection pattern 19m2 including a via portion in contact with the first peripheral circuit interconnection pattern 19m1 and an interconnection portion in contact with the via portion, and a third peripheral circuit interconnection pattern 19m3 on the second peripheral circuit interconnection pattern 19m2. The peripheral interconnection structure 19 may be electrically connected to peripheral interconnection structures (not illustrated) formed in a non-sensing region NSR of the second chip structure 103. In some example embodiments, the peripheral interconnection structure 19 may further include a lower contact plug pattern (not illustrated) in the lower insulating layer 16.

In some example embodiments, the first chip structure 3 may include first and second through-electrode structures 20 and 25. The first through-electrode structures 20 may be the same or substantially the same as the through-electrode structures 20 described with reference to FIGS. 1 and 2.

The second through-electrode structures 25 may penetrate the first substrate 6, the device isolation film 9s, and the lower insulating layer 16 in the non-sensing region NSR. An upper surface of the second through-electrode structures 25 may be coplanar or substantially coplanar with an upper surface of the lower insulating layer 16. The upper surface of the second through-electrode structures 25 may be in contact with a first peripheral circuit interconnection pattern 19m1 on a lower surface of the upper insulating layer 18. Accordingly, the second through-electrode structures 25 may be electrically connected to the peripheral interconnection structures 19. The second through-electrode structures 25 may vertically overlap a region in which a through-hole H of the package substrate 300 is formed.

The second through-electrode structures 25 may be formed in a region vertically overlapping the non-sensing region NSR. In a different view, the second through-electrode structures 25 may not vertically overlap the region in which the through-hole H of the package substrate 300 is formed.

In some example embodiments, the first chip structure 3 may include first and second lower pads 42 and 44. The first lower pads 42 may be the same or substantially the same as the lower pads 40 described with reference to FIGS. 1 and 2.

The second lower pads 44 may be formed on a lower portion of the second through-electrode structures 25. The second lower pads 44 may include the same or substantially the same material as the first lower pads 42.

The second lower pads 44 may be formed in a region vertically overlapping a non-sensing region NSR. In a different view, the second lower pads 44 may not vertically overlap a region in which the through-hole H of the package substrate 300 is formed.

In some example embodiments, the image sensor package 1e may further include connection bumps 60.

The connection bumps 60 may be disposed between upper pads 310 of the package substrate 300 and second lower pads 44 of the first chip structure 3, and may electrically connect the upper pads 310 to the second lower pads 44. Accordingly, the second chip structure 103 may be electrically connected to the interconnection 330 of the package substrate 300 through the second through-electrode structures 25. Accordingly, the second chip structure 103 may not have a plurality of upper pads 180 described with reference to FIGS. 1 and 2. Also, the image sensor package 1e may not have a conductive wire 250 described with reference to FIGS. 1 and 2.

A size of each of the connection bumps 60 may be greater than a size of each of the connection bumps 50. Accordingly, a level of an upper surface of the third chip structure 203 may be the same or substantially the same as or higher than a level of an upper surface of the package substrate 300.

In some example embodiments, an encapsulation layer 600 may cover a side surface of a cover glass 400, an edge of a lower surface of the cover glass 400, a side surface of a bonding dam 500, an edge of an upper surface of the first and second chip structures 3 and 103, a side surface of the first and second chip structures 3 and 103, a side surface of the second lower pads 44, and a side surface of the connection bumps 60 on the package substrate 300.

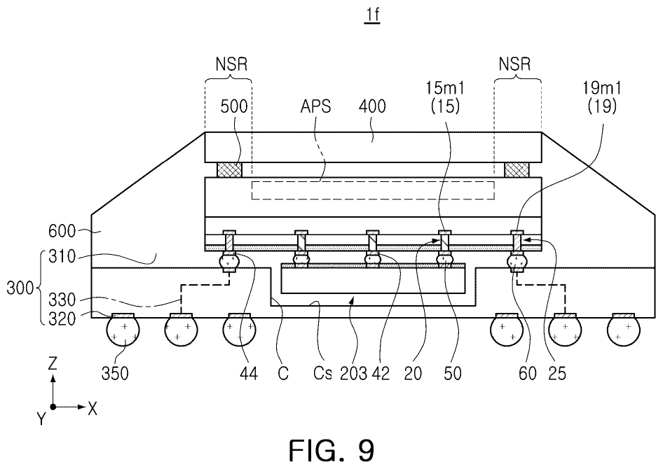

FIG. 9 is a cross-sectional diagram illustrating an image sensor package according to some example embodiments.

Referring to FIG. 9, an image sensor package 1f may be the same as or similar to the configuration described with reference to FIGS. 1 to 8, other than the configuration in which an opening of the package substrate 300 may include a cavity C recessed into an upper portion of the package substrate 300.

As compared to FIG. 8, an opening of the package substrate 300 of the image sensor package 1f may include a cavity C formed by at least a portion of the package substrate 300 being recessed. Accordingly, the package substrate 300 may be defined to have a bottom surface Cs in the cavity C region. In a different view, the cavity C may be recessed into at least a portion of the package substrate 300 and may be defined by the bottom surface Cs of the package substrate 300. Accordingly, a lower surface of the third chip structure 203 disposed in the cavity C may oppose the bottom surface Cs of the package substrate 300. In a different view, the side surfaces and the lower surface of the third chip structure 203 may be surrounded by the package substrate 300.

In some example embodiments, at least a portion of the third chip structure 203 and the external connection terminals 350 may vertically overlap each other.

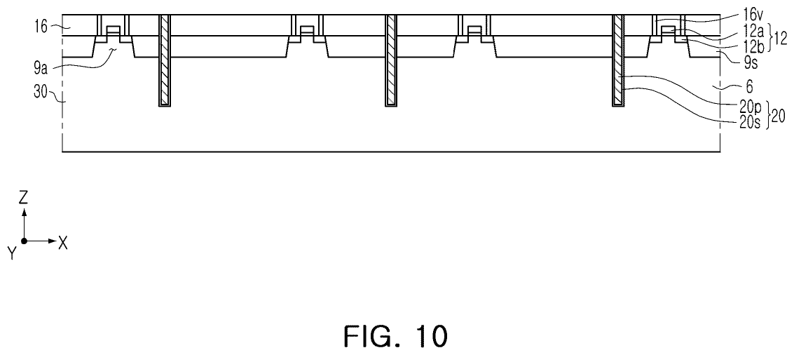

FIGS. 10 to 15 are cross-sectional diagrams illustrating a manufacturing method of an image sensor package 1 according to some example embodiments according to a process sequence.

Referring to FIG. 10, a first substrate 6, a device isolation film 9s defining an active region 9a on the first substrate 6, a gate 12a on the active region 9a, a source/drain 9b formed on at least one side of the gate 12a on the active region 9a, and a lower insulating layer 16 covering the gate 12a and the source/drain 9b may be formed. Thereafter, by the lower insulating layer 16 being recessed, a lower contact plug 16v and a through-electrode structure 20 may be formed.

The device isolation film 9s may be formed by forming a predetermined (or, alternatively, desired or determined) trench defining the active region 9a by patterning the first substrate 6, and filling the trench with an insulating material.

An insulating material layer and a gate electrode material layer may be deposited on the device isolation film 9s in order, and a gate insulating film and gate 12a may be formed through a photo-process using a mask. Thereafter, a source/drain 12b may be formed on at least one side of the gate 12a.

The lower insulating layer 16 may be formed on the device isolation film 9s and the circuit device 12.

Openings penetrating the lower insulating layer 16 and exposing an upper surface of the source/drain 12b may be formed. By filling the openings with a conductive material, the lower contact plug 16v may be formed.

Open portions penetrating the lower insulating layer 16 and the device isolation film 9s and exposing at least a portion of the first substrate 6 may be formed. An insulating material may be deposited on a surface of the open portions and a conductive material may be filled therein. Thereafter, a planarization process may be performed, and the through-electrode structure 20 may be formed.

In some example embodiments, the through-electrode structure 20 may be formed in a different order from the above-described processes. For example, the through-electrode structure 20 described with reference to FIG. 4 may be formed before the gate 12a is formed. Before the gate 12a is formed, open portions penetrating the device isolation film 9s and exposing at least a portion of the first substrate 6 may be formed. An insulating material may be deposited on a surface of the open portions and a conductive material may be filled therein. Thereafter, a planarization process may be performed and a through-electrode structure 20 may be formed. Thereafter, a lower insulating layer 16 covering the gate 12a, the source/drain 12b, the gate 12a and the source/drain 12b may be formed. Thereafter, openings penetrating the lower insulating layer 16 and exposing an upper surface of the source/drain 12b and an upper surface of the through-electrode structure 20 may be formed. By filling a conductive material in the openings, lower contact plugs 16v connected to the source/drain 12b and the through-electrode structure 20, respectively, may be formed (see FIG. 4).

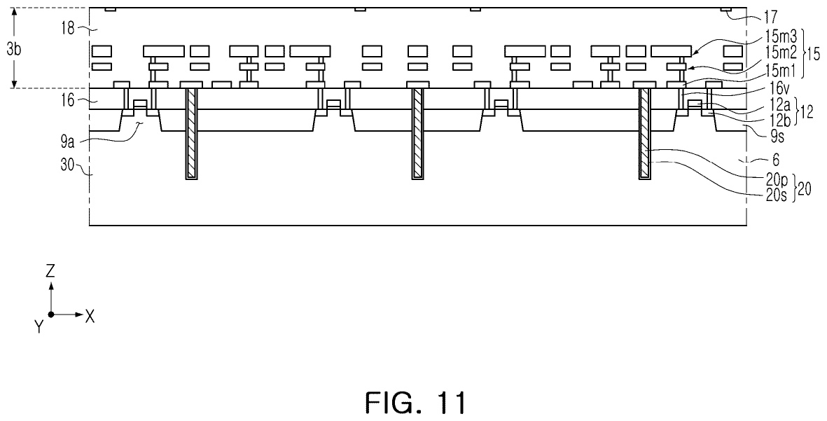

Referring to FIG. 11, a first interconnection structure 15 and an upper insulating layer 18 may be formed on the lower insulating layer 16.

A first circuit interconnection pattern 15m1 may be formed on lower contact plugs 16v and through-electrode structures 20, a second circuit interconnection pattern 15m2 connected to the first circuit interconnection pattern 15m1, and a third circuit interconnection pattern 15m3 connected to the second circuit interconnection pattern 15m2 may be formed in order.

The upper insulating layer 18 may be formed in a plurality of layers (not illustrated). The upper insulating layer 18 may have, for example, a boundary surface (not illustrated) between the circuit interconnection patterns 15m1, 15m2, and 15m3.

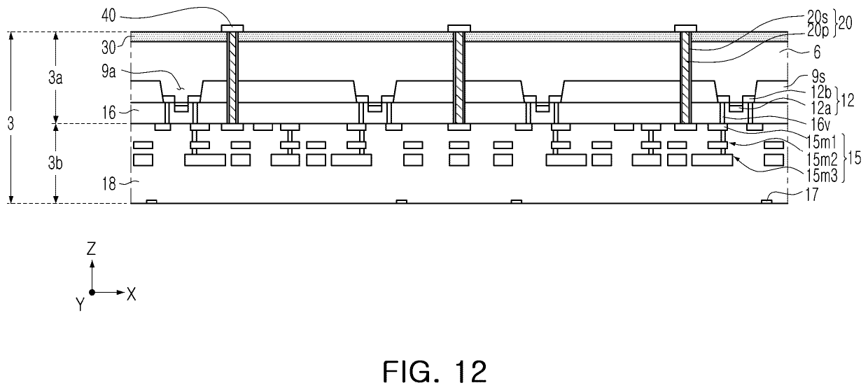

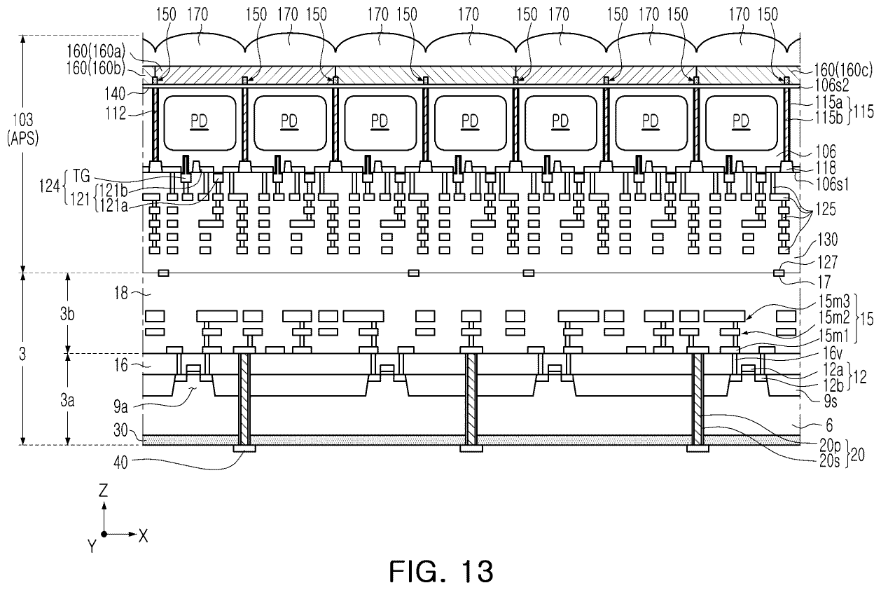

Thereafter, to bond the first chip structure (“3” in FIG. 12) with the second chip structure (“103” in FIG. 13), first chip pads 17 may be formed on the upper insulating layer 18. Accordingly, a second region 3b of the first chip structure (“3” in FIG. 2) may be defined.

Referring to FIG. 12, a passivation layer 30 and lower pads 40 may be formed.

The semiconductor structure according to FIG. 11 may be flipped upwardly such that a back surface of the first substrate 6 may be upwardly exposed. The back surface of the first substrate 6 may be ground such that an upper region of the through-electrode structure 20 may be exposed. Accordingly, an upper surface of the pillar pattern 20p may be exposed. By depositing an insulating material layer, a passivation layer 30 covering the upper region of the exposed through-electrode structure 20 may be formed. Thereafter, an upper surface of the pillar pattern 20p may be exposed again through a planarization process. Thereafter, lower pads 40 may be formed on an upper surface of the pillar pattern 20p. Accordingly, a first region 3a may be defined. Accordingly, a first chip structure 3 including first and second regions 3a and 3b may be formed.

According to some example embodiments, the through-electrode structure 20 may be formed in a different order from the above-described processes. For example, the through-electrode structure 20 described with reference to FIG. 5 may be formed after the upper insulating layer 18 is formed. After the upper insulating layer 18 is formed, open portions penetrating the upper insulating layer 18, the lower insulating layer 16, and the device isolation film 9s and exposing at least a portion of the first substrate 6 may be formed. An insulating material may be deposited on surfaces of the open portions and a conductive material may be filled therein. Thereafter, a planarization process may be performed and a through-electrode structure 20 may be (see FIG. 5). Thereafter, the processes described with reference to FIG. 12 may be performed, and a passivation layer 30 and lower pads 40 may be formed.

Referring to FIG. 13, the first chip structure 3 and the second chip structure 103 may be bonded to each other.

A second chip structure 103 having an active pixel sensor region APS and a non-sensing region (NSR, see FIG. 1) may be provided. Forming the second chip structure 103 may include preparing a second substrate 106 having a first surface 106s1 and a second surface 106s2 opposing each other, forming an isolation structure 115 and photoelectric conversion devices PD in the second substrate 106, forming a device isolation film 118 defining an active region on the first surface 106s1 of the second substrate 106, forming a second circuit device 124 on the first surface 106s1 of the second substrate 106, and forming a second interconnection structure 125 and a second chip pad 127 on the first surface 106s1 of the second substrate 106, and a second insulating layer 130 covering the second circuit device 124, the second interconnection structure 125 and the second chip pad 127. The order of forming the isolation structure 115, the photoelectric conversion devices PD and the device isolation film 118 may be varied.

Thereafter, the first chip structure 3 and the second chip structure 103 may be bonded to each other by performing a wafer bonding process for bonding two wafers. Here, the second chip structure 103 may include a second substrate 106, photoelectric conversion devices PD, isolation structures 115, and a second insulating layer 130. The first insulating layer 18 of the first chip structure 3 and the second insulating layer 130 of the second chip structure 103 may be bonded to each other. The first chip pads 17 of the first chip structure 3 and the second chip pads 127 of the second chip structure 103 may be bonded to each other.

A grinding process for reducing the thickness of the second substrate 106 of the second chip structure 103 may be performed, thereby exposing the isolation structure 115 in the second substrate 106.

Thereafter, a horizontal insulating layer 140 may be conformally deposited on the second surface 106s2 of the second substrate 106 of which a thickness is reduced. By performing a deposition process multiple times, the horizontal insulating layer 140 may be formed in a multilayer structure.

A grid pattern 150 may be formed on the horizontal insulating layer 140. The grid pattern 150 may be formed by performing a process for depositing an insulating material, for example, an oxide or nitride, and a patterning process.

Thereafter, color filters 160 and microlenses 170 may be formed in order. The color filters 160 may be formed on the horizontal insulating layer 140, and microlenses 170 may be formed on the color filters 160. In some example embodiments, the color filters 160 may cover the grid pattern 150, but some example embodiments thereof are not limited thereto. The color filters 160 may be formed in the active pixel sensor region APS. Accordingly, a second chip structure 103 may be provided on the first chip structure 3.

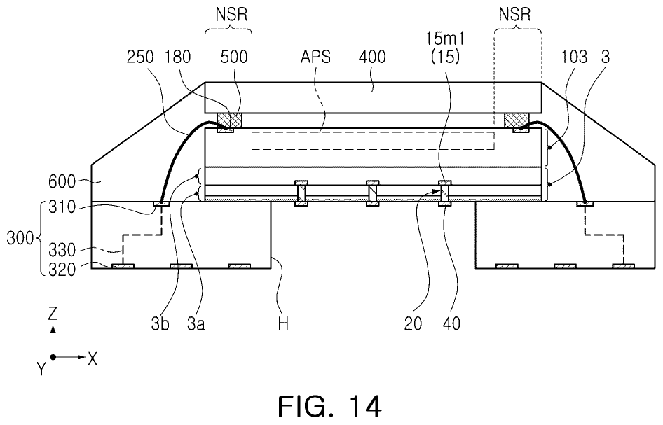

Referring to FIG. 14, the first and second chip structures 3 and 103 may be mounted on a package substrate 300.

A package substrate 300 having an upper pad 310, a lower pad 320, an interconnection 330 electrically connecting the upper pad 310 to the lower pad 320, and a through-hole H may be provided. The first and second chip structures 3 and 103 may be mounted on the package substrate 300 such that the lower pads 40 of the first chip structure 3 may vertically overlap a region in which a through-hole H is formed.

Thereafter, a conductive wire 250 electrically connecting upper pads 180 of the second chip structure 103 to upper pads 310 of the package substrate 300 may be formed. A bonding dam 500 may be formed on a non-sensing region NSR of the second chip structure 103. A cover glass 400 may be formed on the bonding dam 500. An encapsulation layer 600 covering side surfaces of the first and second chip structures 3 and 103, the side surface of the bonding dam 500, and the side surface of the cover glass 400 may be formed on the package substrate 300.

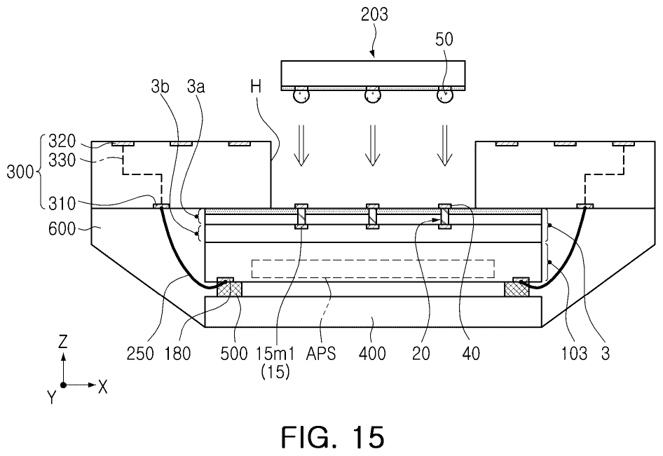

Referring to FIG. 15, a third chip structure 203 may be provided in the through-hole H region of the package substrate 300.

The third chip structure 203 may be vacuum-absorbed into a bonding device and may be picked and placed in the through-hole H. The third chip structure 203 provided in the through-hole H may be attached to the first chip structure 3. For example, connection bumps 50 may be attached to the lower pads 40 of the first chip structure 3.

The third chip structure 203 may be disposed on the first chip structure 3 without the connection bumps 50 (see FIG. 3). The third chip structure 203 may be disposed such that active pads 230 of the third chip structure 203 may be directly bonded to through-electrode structures 20 of the first chip structure 3. In this case, the lower pads (“40” in FIG. 2) of the first chip structure 3 may not be formed.

Differently from the above-described processes, after the third chip structure 203 is provided in the through-hole H region, the conductive wire 250, the bonding dam 500, the cover glass 400, and the encapsulation layer 600 may be formed subsequently. For example, after the first and second chip structures 3 and 103 are mounted on the package substrate 300, the third chip structure 203 may be provided in the through-hole H region of the package substrate 300. Thereafter, the conductive wire 250, the bonding dam 500, the cover glass 400, and the encapsulation layer 600 may be formed.

Thereafter, external connection terminals 350 may be formed on the lower pads 320 of the package substrate 300, such that an image sensor package 1 may be provided.

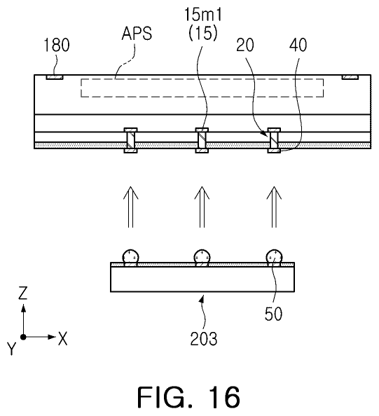

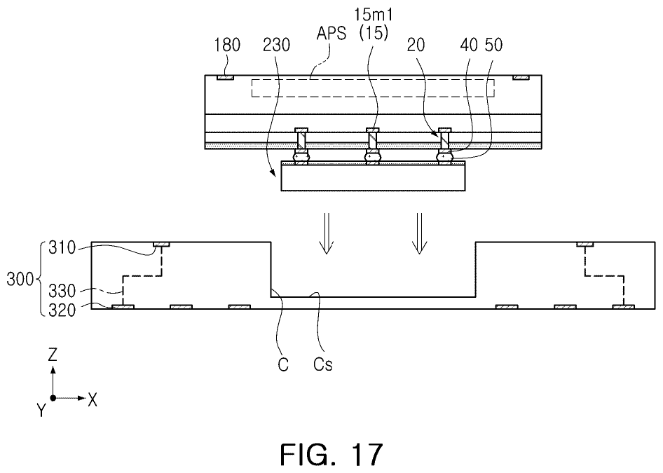

FIGS. 16 and 17 are cross-sectional diagrams illustrating processes of a method of manufacturing an image sensor package in order according to some example embodiments. FIG. 16 may be a process diagram subsequent to the processes described with reference to FIG. 12.

Referring to FIG. 16, a third chip structure 203 may be disposed on the first and second chip structures 3 and 103.

The third chip structure 203 may be disposed on a lower portion of the first chip structure 3 such that connection bumps 50 may be attached to the lower pads 40 of the first chip structure 3.

Referring to FIG. 17, the first to third chip structures 3, 103, and 203 may be mounted on a package substrate 300.

A package substrate 300 having an upper pad 310, a lower pad 320, an interconnection 330 electrically connecting the upper pad 310 to the lower pad 320, and a cavity C may be provided.

The first to third chip structures 3, 103, and 203 may be mounted on the package substrate 300 such that the third chip structure 203 may be disposed in the cavity C of the package substrate 300. In a different view, the third chip structure 203 may be disposed such that a lower surface of the third chip structure 203 may oppose a bottom surface Cs of the cavity C of the package substrate 300.

Thereafter, similarly to some example embodiments described with reference to FIG. 14, a conductive wire 250 electrically connecting upper pads 180 of the second chip structure 103 to upper pads 310 of the package substrate 300 may be formed. A bonding dam 500 may be formed on the non-sensing region NSR of the second chip structure 103. A cover glass 400 may be formed on the bonding dam 500. An encapsulation layer 600 covering side surfaces of the first and second chip structures 3 and 103, the side surface of the bonding dam 500, and the side surface of the cover glass 400 on the package substrate 300 may be formed.

Thereafter, external connection terminals 350 may be formed on lower pads 320 of the package substrate 300, thereby providing an image sensor package 1d.

The image sensor package 1e in FIGS. 7 and 8 may be provided through processes similar to some example embodiments described with reference to FIGS. 10 to 15.

For example, differently from described with reference to FIG. 10, forming the first chip structure 3 in FIG. 8 may include forming through-electrode structures 20 in an active pixel sensor region APS of a first substrate 6, and forming through-electrode structures 25 in the non-sensing region NSR of the first substrate 6.

Thereafter, differently from described with reference to FIG. 14, the mounting the first and second chip structures 3 and 103 in FIG. 8 on the package substrate 300 may include attaching connection bumps 60 on lower pads 44 of the non-sensing region NSR to upper pads 310 of the package substrate 300. Thereafter, similarly to the process described in FIG. 15, after a third chip structure 203 is provided in the through-hole H region, a bonding dam 500, a cover glass 400 and an encapsulation layer 600 may be formed subsequently. Accordingly, the image sensor package 1e in FIGS. 7 and 8 may be provided.

The image sensor package 1f in FIG. 9 may be provided through processes similar to some example embodiments described with reference to FIGS. 7, 8, 16 and 17.

For example, the forming the first chip structure 3 in FIG. 9 may be the same or substantially the same as the forming the first chip structure 3 in FIG. 8.

Thereafter, the third chip structure 203 may be disposed on a lower portion of the first chip structure 3 such that the connection bumps 50 may be attached to lower pads 42 of the first chip structure 3.

Thereafter, the first to third chip structures 3, 103, and 203 in FIG. 9 may be disposed on the package substrate 300 such that the connection bumps 60 on the lower pads 44 of the non-sensing region NSR may be attached to the upper pads 310 and the third chip structure 203 may be disposed in the cavity C.

Thereafter, the bonding dam 500, the cover glass 400, and the encapsulation layer 600 may be formed subsequently. Accordingly, the image sensor package 1f in FIG. 9 may be provided.

According to the aforementioned example embodiments, the image sensor package including a package substrate having an opening formed therein and a chip structure disposed in the opening, and a method of manufacturing the same may be provided.

Specifically, according to some example embodiments, by disposing a chip structure in a through-hole or cavity of a package substrate, the chip structure may be physically spaced apart from an external connection terminal. Accordingly, physical damages to the chip structure received from the external connection terminal may be reduced or prevented. Also, by forming a through-electrode structure in the chip structure disposed on an upper portion of the package substrate, a signal delay between a plurality of chip structures of the image sensor package may be addressed and/or improved.

When the terms “about” or “substantially” are used in this specification in connection with a numerical value, it is intended that the associated numerical value includes a manufacturing or operational tolerance (e.g., ±10%) around the stated numerical value. Moreover, when the words “generally” and “substantially” are used in connection with geometric shapes, it is intended that precision of the geometric shape is not required but that latitude for the shape is within the scope of the disclosure. Further, regardless of whether numerical values or shapes are modified as “about” or “substantially,” it will be understood that these values and shapes should be construed as including a manufacturing or operational tolerance (e.g., ±10%) around the stated numerical values or shapes.

While some example embodiments have been illustrated and described above, it will be apparent to those skilled in the art that modifications and variations could be made without departing from the scope of the present disclosure as defined by the appended claims.

What is claimed is:

1. An image sensor package, comprising:
a package substrate defining an opening region, the package substrate including a plurality of bonding pads;
a logic chip on the package substrate, the logic chip comprising a substrate and an interconnection structure;
an image sensor chip on the logic chip, the image sensor chip comprising an active pixel sensor region and a non-sensing region having a plurality of chip pads;
an interface chip in the opening region of the package substrate,
the interface chip comprising
an active surface including a plurality of active pads, the active surface opposing a lower surface of the logic chip; and
an inactive surface opposite the active surface, and
the logic chip comprising first through-electrode structures penetrating the substrate of the logic chip and electrically connecting the interconnection structure of the logic chip and the plurality of active pads of the interface chip.

2. The image sensor package of claim 1, wherein the logic chip further comprises a passivation layer on a lower portion of the substrate and surrounding a lower region of the first through-electrode structures.

3. The image sensor package of claim 1, further comprising:
a conductive wire electrically connecting the plurality of bonding pads of the package substrate and the plurality of chip pads of the image sensor chip.

4. The image sensor package of claim 1,
wherein the logic chip comprises:
a lower insulating structure on the substrate; and
an upper insulating structure on the lower insulating structure, and
wherein the interconnection structure of the logic chip comprises:
a lower contact plug pattern in the lower insulating structure; and
a plurality of circuit interconnection patterns in the upper insulating structure, the plurality of circuit interconnection patterns have a first circuit interconnection pattern in contact with the lower contact plug pattern.

5. The image sensor package of claim 4, wherein at least a portion of the first through-electrode structures extends upwardly to penetrate the lower insulating structure and is in contact with a lower surface of the first circuit interconnection pattern.

6. The image sensor package of claim 4, wherein at least a portion of the first through-electrode structures is in contact with a lower surface of the lower contact plug pattern of the interconnection structure of the logic chip.

7. The image sensor package of claim 4,
wherein the image sensor chip further comprises a plurality of bonding pads on a lower portion, and
wherein at least a portion of the first through-electrode structures extends upwardly to penetrate the lower insulating structures and the upper insulating structures and is in contact with a lower surface of at least a portion of the plurality of bonding pads.

8. The image sensor package of claim 1, wherein the plurality of active pads on the interface chip are in contact with lower surfaces of the first through-electrode structures.

9. The image sensor package of claim 1,
wherein the logic chip further comprises a plurality of first lower pads covering lower surfaces of the first through-electrode structures, and
wherein the image sensor package further comprises first connection bumps between the plurality of first lower pads of the logic chip and the plurality of active pads of the interface chip.

10. The image sensor package of claim 1,
wherein the logic chip further comprises:
second through-electrode structures penetrating the substrate in a region overlapping the non-sensing region of the image sensor chip; and
a plurality of second lower pads covering lower surfaces of the second through-electrode structures, and
wherein the image sensor package further comprises second connection bumps between the plurality of second lower pads of the logic chip and the plurality of bonding pads of the package substrate.

11. The image sensor package of claim 1, wherein a level of a lower surface of the interface chip is higher than a level of a lower surface of the package substrate.

12. The image sensor package of claim 1, wherein the opening region of the package substrate comprises a through-hole region penetrating the package substrate.

13. The image sensor package of claim 1, wherein the opening region of the package substrate has a cavity recessed into at least a portion of the package substrate and defined by a bottom surface of the package substrate.

14. The image sensor package of claim 1, further comprising:
a bonding dam around the active pixel sensor region;
a cover glass on an upper portion of the bonding dam and the image sensor chip; and
an encapsulation layer covering a side surface of the bonding dam, a side surface of the cover glass, an edge of a lower surface of the cover glass, the non-sensing region, and an edge of an upper surface of the package substrate.

15. An image sensor package, comprising:
a package substrate defining an opening region; and
a first logic chip on the package substrate, the first chip covering the opening region,
the first logic chip comprising
a substrate;
an insulating structure on the substrate, the insulating structure comprising conductive patterns;
a passivation layer on a lower portion of the substrate; and
through-electrode structures penetrating the substrate and the passivation layer and electrically connected to the conductive patterns, and
an image sensor chip on an upper portion of the first logic chip; and
a second logic chip on a lower portion of the first logic chip in the opening region of the package substrate and electrically connected to the through-electrode structures of the first logic chip.

16. The image sensor package of claim 15,
wherein the conductive patterns comprise a plurality of circuit interconnection patterns, and
wherein the through-electrode structures are in contact with a lowermost circuit interconnection pattern among the plurality of circuit interconnection patterns.

17. The image sensor package of claim 15, wherein a level of an upper surface of the second logic chip is between a level of an upper surface and a level of a lower surface of the package substrate.

18. The image sensor package of claim 15, wherein the second logic chip comprises:
a base substrate comprising active pads electrically connected to the through-electrode structures;
an interface chip on the base substrate; and
an encapsulant covering the interface chip on the base substrate.

19. An image sensor package, comprising:
a package substrate defining an opening region, the package substrate including a plurality of bonding pads; and
a logic chip on the package substrate, the logic chip covering the opening region,
the logic chip including
a substrate;
a lower insulating structure on the substrate;
an upper insulating structure on the lower insulating structure, the upper insulating structure including a plurality of circuit interconnection patterns;
a passivation layer on a lower portion of the substrate; and
through-electrode structures penetrating the passivation layer, the substrate, and the lower insulating structure and in contact with a lowermost circuit interconnection pattern among the plurality of circuit interconnection patterns,
an image sensor chip on the logic chip, the image sensor chip including an active pixel sensor region and non-sensing region having and a plurality of chip pads;
a conductive wire electrically connecting the plurality of bonding pads of the package substrate and the plurality of chip pads of the image sensor chip; and
an interface chip on a lower portion of the logic chip in the opening region of the package substrate and electrically connected to the through-electrode structures of the logic chip.

20. The image sensor package of claim 19,
wherein the interface chip includes:
an active surface including active pads electrically connected to the through-electrode structures of the logic chip; and
an inactive surface opposite of the active surface,
wherein the active surface opposes a lower surface of the passivation layer, and
wherein a level of the active surface is between a level of an upper surface of the package substrate and a level of the lower surface.
